(19) United States
(12) Patent Application Publication
(10) Pub. No.: US 2018/0034240 A1
(43) Pub. Date: Feb. 1, 2018

(54) FAILURE DETECTION OF LASER DIODES

(71) Applicant: Applied Materials, Inc., Santa Clara, CA (US)

(72) Inventor: Wenwei QIAO, Gilroy, CA (US)

(21) Appl. No.: 15/553,436

(22) PCT Filed: Mar. 17, 2016
(86) PCT No.: PCT/US2016/022848

§ 371 Date: Aug. 24, 2017

Related U.S. Application Data
(60) Provisional application No. 62/135,875, filed on Mar. 20, 2015.

(51) Int. Cl. H01S 5/068; H01S 5/40; H01S 5/00

(52) U.S. Cl. CPC H01S 5/06825; H01S 5/0028; H01S 5/4018; G03F 7/0002

(57) ABSTRACT

Embodiments described herein generally relate to an apparatus and method for performing photolithography processes. More particularly, embodiments described herein generally relate to an apparatus and method for the digital control of optical-coupled solid state relays employed on a laser diode. Digital control of the optical-coupled solid state relays may allow for the turning on and/or turning off of the optical-coupled solid state relays and allow for the failure detection of each laser diode. Furthermore, the embodiments described herein allow for an increase in current provided to the laser diodes such that overall laser diode output for optimized illumination may be maintained while life time and tool reliability are also increased.

### BACKGROUND

### Field

Embodiments of the present disclosure generally relate to the field of maskless lithography. More specifically, embodiments provided herein relate to a system and method for performing maskless digital lithography manufacturing processes.

### Description of the Related Art

Photolithography is widely used in the manufacturing of semiconductor devices and display devices, such as liquid crystal displays (LCDs). Large area substrates are often utilized in the manufacture of LCDs. LCDs, or flat panels, are commonly used for active matrix displays, such as computers, touch panel devices, personal digital assistants (PDAs), cell phones, television monitors, and the like. Generally, flat panels may include a layer of liquid crystal material forming pixels sandwiched between two plates. When power from the power supply is applied across the liquid crystal material, an amount of light passing through the liquid crystal material may be controlled at pixel locations enabling images to be generated.

Microlithography techniques are generally employed to create electrical features incorporated as part of the liquid crystal material layer forming the pixels. According to this technique, a light-sensitive photoresist is typically applied to at least one surface of the substrate. Then, a pattern generator exposes selected areas of the light-sensitive photoresist as part of a pattern with light to cause chemical changes to the photoresist in the selective areas to prepare these selective areas for subsequent material removal and/or material addition processes to create the electrical features.

In order to continue to provide display devices and other devices to consumers at the prices demanded by consumers, new apparatuses, approaches, and systems are needed to precisely and cost-effectively create patterns on substrates, such as large area substrates.

A control circuit is able to control a single laser diode. The control circuit is important to maintain the overall diode output for optimized illumination of a laser diode. However, tools that apply laser diodes with higher powered currents require a reduction in the overall switching current per power supply limit, as a laser diode is a current device and not a voltage device.

As the foregoing illustrates, there is a need for an improved laser diode control circuit for the failure detection of laser diodes. More specifically, what is needed in the art is an optical-coupled solid state relay which is employed on a laser diode and acts as a digital control for turning on and off the relays.

### SUMMARY

The present disclosure generally relates to an apparatus and method of performing photolithography processes. More particularly, embodiments described herein generally relate to an apparatus and method for the digital control of optical-coupled solid state relays employed on a laser diode. Digital control of the optical-coupled solid state relays may allow for the turning on and/or turning off of the relays and allow for the failure detection of each laser diode. Furthermore, the embodiments described herein allow for an increase in current provided to the laser diodes such that overall laser diode output for optimized illumination may be maintained while life time and tool reliability are also increased.

In one embodiment, a processing apparatus is disclosed. The processing apparatus comprises a laser source, and a control circuit comprising at least one laser diode and a relay coupled with each of the at least one laser diode, wherein the relay provides digital control of the at least one laser diode.

In another embodiment, a processing apparatus is disclosed. The processing apparatus includes a control circuit. The control circuit includes two or more diodes connected in a series connection and an optical-coupled solid state relay connected with each diode. Each optical-coupled solid state relay provides digital control of a respective laser diode.

In yet another embodiment, a method for detecting the failure of a laser diode is disclosed. The method includes digitally scanning a relay, wherein the relay is connected with the laser diode, driving control current to the laser diode, and measuring the optic output intensity at the relay of each laser diode.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of this disclosure and are therefore not to be considered limiting of its scope, for the disclosure may to other equally effective embodiments.

FIG. 1 is a perspective view of a system that may benefit from embodiments disclosed herein.

FIG. 2 is a cross-sectional side view of the system of FIG. 1 according to one embodiment.

FIG. 3 is a perspective schematic view of a plurality of image projection systems according to one embodiment.

FIG. 4 is a perspective schematic view of an image projection system of the plurality of image projection devices of FIG. 3 according to one embodiment.

FIG. 5 schematically illustrates a beam being reflected by the two mirrors of the DMD of FIG. 5 according to one embodiment.

FIG. 6 is a perspective view of an image projection apparatus according to one embodiment.

FIG. 7 is a perspective schematic view of a system employing serialized multiple laser diodes.

FIG. 8 is a perspective schematic view of a system with optical-coupled solid state relays employed on each laser diode according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to the failure detection of laser diodes. Optical-coupled solid state relays are employed on each laser diode. The turning on and/or turning off of each relay may be controlled digitally. The laser control circuits for detecting the failure of laser diodes are described below and in the attached appendix.

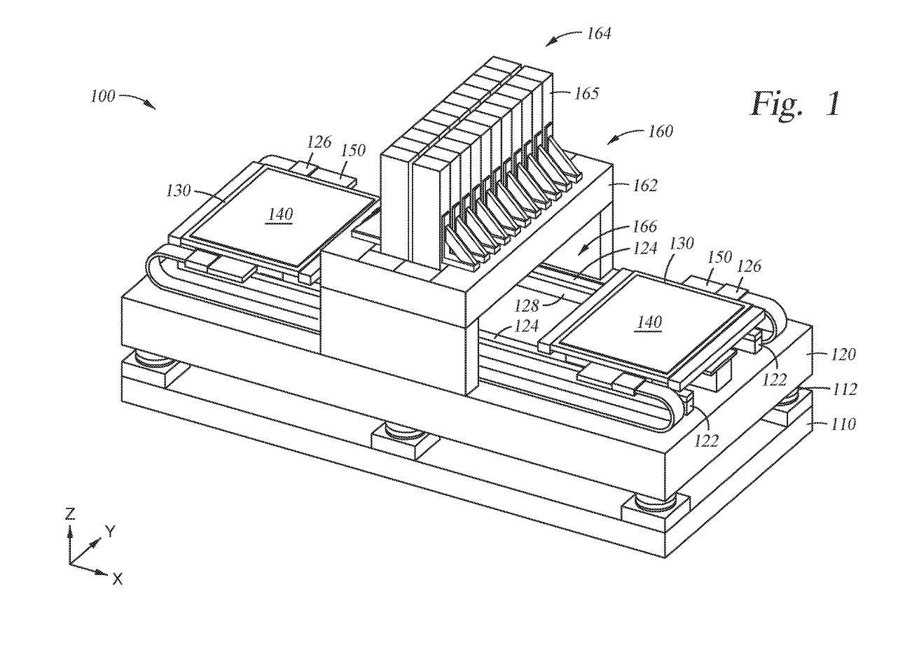

FIG. 1 is a perspective view of a system 100 that may benefit from embodiments disclosed herein. The system 100 includes a base frame 110, a slab 120, two or more stages 130, and a processing apparatus 160. The base frame 110 may rest on the floor of a fabrication facility and may support the slab 120. Passive air isolators 112 may be positioned between the base frame 110 and the slab 120. The slab 120 may be a monolithic piece of granite, and the two or more stages 130 may be disposed on the slab 120. A substrate 140 may be supported by each of the two or more stages 130. A plurality of holes (not shown) may be formed in the stage 130 for allowing a plurality of lift pins (not shown) to extend therethrough. The lift pins may rise to an extended position to receive the substrate 140, such as from a transfer robot (not shown). The transfer robot may position the substrate 140 on the lift pins, and the lift pins may thereafter gently lower the substrate 140 onto the stage 130.

The substrate 140 may, for example, be made of quartz and be used as part of a flat panel display. In other embodiments, the substrate 140 may be made of other materials. In some embodiments, the substrate 140 may have a photoresist layer formed thereon. A photoresist is sensitive to radiation and may be a positive photoresist or a negative photoresist, meaning that portions of the photoresist exposed to radiation will be respectively soluble or insoluble to a photoresist developer applied to the photoresist after the pattern is written into the photoresist. The chemical composition of the photoresist determines whether the photoresist will be a positive photoresist or negative photoresist. For example, the photoresist may include at least one of diazonaphthoquinone, a phenol formaldehyde resin, poly(methyl methacrylate), poly(methyl glutarimide), and SU-8. In this manner, the pattern may be created on a surface of the substrate 140 to form the electronic circuitry.

The system 100 may further include a pair of supports 122 and a pair of tracks 124. The pair of supports 122 may be disposed on the slab 120, and the slab 120 and the pair of supports 122 may be a single piece of material. The pair of tracks 124 may be supported by the pair of the supports 122, and the two or more stages 130 may move along the tracks 124 in the X-direction. In one embodiment, the pair of tracks 124 is a pair of parallel magnetic channels. As shown, each track 124 of the pair of tracks 124 is linear. In other embodiments, the track 124 may have a non-linear shape. An encoder 126 may be coupled to each stage 130 in order to provide location information to a controller (not shown).

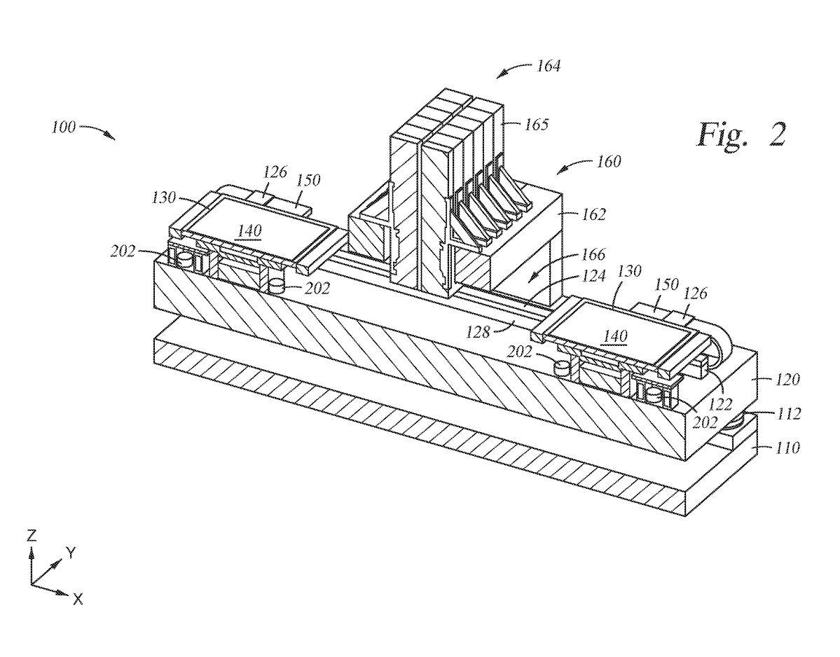

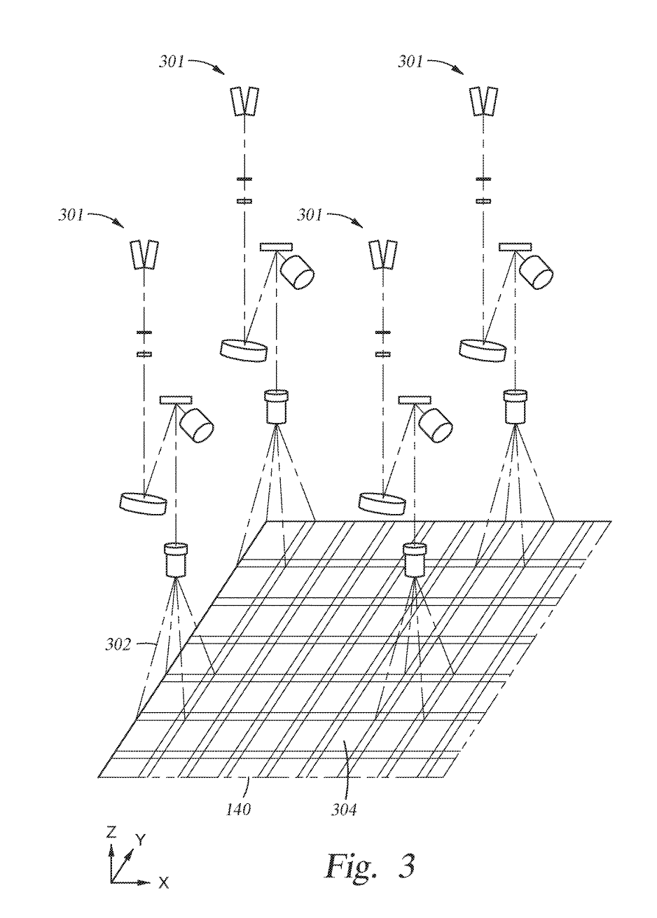

The processing apparatus 160 may include a support 162 and a processing unit 164. The support 162 may be disposed on the slab 120 and may include an opening 166 for the two or more stages 130 to pass under the processing unit 164. The processing unit 164 may be supported by the support 162. In one embodiment, the processing unit 164 is a pattern generator configured to expose a photoresist in a photolithography process. In some embodiments, the pattern generator may be configured to perform a maskless lithography process. The processing unit 164 may include a plurality of image projection systems (shown in FIG. 3) disposed in a case 165. The processing apparatus 160 may be utilized to perform maskless direct patterning. During operation, one of the two or more stages 130 moves in the X-direction from a loading position, as shown in FIG. 1, to a processing position. The processing position may refer to one or more positions of the stage 130 as the stage 130 passes under the processing unit 164. During operation, the two or more stages 130 may be lifted by a plurality of air bearings 202 (shown in FIG. 2) and may move along the pair of tracks 124 from the loading position to the processing position. A plurality of vertical guide air bearings (not shown) may be coupled to each stage 130 and positioned adjacent an inner wall 128 of each support 122 in order to stabilize the movement of the stage 130. Each of the two or more stages 130 may also move in the Y-direction by moving along a track 150 for processing and/or indexing the substrate 140.

FIG. 2 is a cross-sectional side view of the system 100 of FIG. 1 according to one embodiment. As shown, each stage 130 includes a plurality of air bearings 202 for lifting the stage 130. Each stage 130 may also include a motor coil (not shown) for moving the stage 130 along the tracks 124. The two or more stages 130 and the processing apparatus 160 may be enclosed by an enclosure (not shown) in order to provide temperature and pressure control.

The system 100 also includes a controller (not shown). The controller is generally designed to facilitate the control and automation of the processing techniques described herein. The controller may be coupled to or in communication with one or more of the processing apparatus 160, the stages 130, and the encoder 126. The processing apparatus 160 and the stages 130 may provide information to the controller regarding the substrate processing and the substrate aligning. For example, the processing apparatus 160 may provide information to the controller to alert the controller that substrate processing has been completed. The encoder 126 may provide location information to the controller, and the location information is then used to control the stages 130 and the processing apparatus 160.

The controller may include a central processing unit (CPU) (not shown), memory (not shown), and support circuits (or I/O) (not shown). The CPU may be one of any form of computer processors that are used in industrial settings for controlling various processes and hardware (e.g., pattern generators, motors, and other hardware) and monitor the processes (e.g., processing time and substrate position). The memory (not shown) is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits (not shown) are also connected to the CPU for supporting the processor in a conventional manner. The support circuits may include conventional cache, power supplies, clock circuits, input/output circuitry, subsystems, and the like. A program (or computer instructions) readable by the controller determines which tasks are performable on a substrate. The program may be software readable by the controller and may include code to monitor and control, for example, the processing time and substrate position.

FIG. 3 is a perspective schematic view of a plurality of image projection systems 301 according to one embodiment. As shown in FIG. 3, each image projection system 301 produces a plurality of write beams 302 onto a surface 304 of the substrate 140. As the substrate 140 moves in the X-direction and Y-direction, the entire surface 304 may be patterned by the write beams 302. The number of the image projection systems 301 may vary based on the size of the substrate 140 and/or the speed of stage 130. In one embodiment, there are 22 image projection systems 301 in the processing apparatus 160.

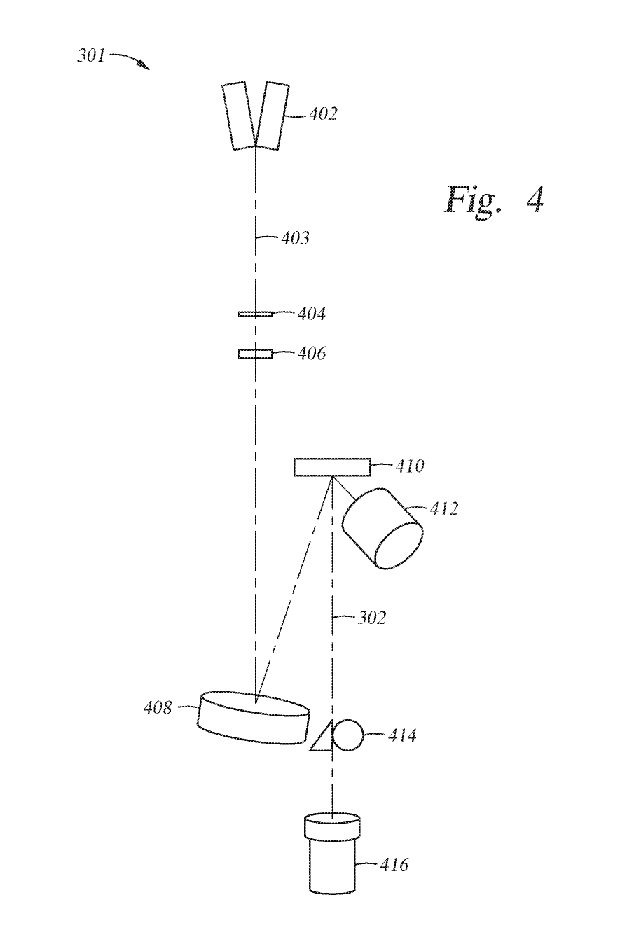

FIG. 4 is a perspective schematic view of one image projection system 301 of the plurality of image projection systems 301 of FIG. 3 according to one embodiment. The image projection system 301 may include a light source 402, an aperture 404, a lens 406, a mirror 408, a DMD 410, a light dump 412, a camera 414, and a projection lens 416. The light source 402 may be a light emitting diode (LED) or a laser, and the light source 402 may be capable of producing a light having predetermined wavelength. In one embodiment, the predetermined wavelength is in the blue or near ultraviolet (UV) range, such as less than about 450 nm. The mirror 408 may be a spherical mirror. The projection lens 416 may be a 10× objective lens. The DMD 410 may include a plurality of mirrors, and the number of mirrors may correspond to the resolution of the projected image. In one embodiment, the DMD 410 includes 1920×1080 mirrors, which represent the number of pixels of a high definition television or other flat panel displays.

During operation, a beam 403 having a predetermined wavelength, such as a wavelength in the blue range, is produced by the light source 402. The beam 403 is reflected to the DMD 410 by the mirror 408. The DMD 410 includes a plurality of mirrors that may be controlled individually, and each mirror of the plurality of mirrors of the DMD 410 may be at “on” position or “off” position, based on the mask data provided to the DMD 410 by the controller (not shown). When the beam 403 reaches the mirrors of the DMD 410, the mirrors that are at “on” position reflect the beam 403, i.e., forming the plurality of write beams 302, to the projection lens 416. The projection lens 416 then projects the write beams 302 to the surface 304 of the substrate 140. The mirrors that are at “off” position reflect the beam 403 to the light dump 412 instead of the surface 304 of the substrate 140.

In one embodiment, the DMD 410 may have two mirrors. Each mirror may be disposed on a tilting mechanism, which may be disposed on a memory cell. The memory cell may be a CMOS SRAM. During operation, each mirror is controlled by loading the mask data into the memory cell. The mask data electrostatically controls the tilting of the mirror in a binary fashion. When the mirror is in a reset mode or without power applied, it may be set to a flat position, not corresponding to any binary number. Zero in binary may correspond to an “off” position, which means the mirror is tilted at −10 degrees, −12 degrees, or any other feasibly negative tilting degree. One in binary may correspond to an “on” position, which means the mirror is tilted at +10 degrees, +12 degrees, or any other feasibly positive tilting degree.

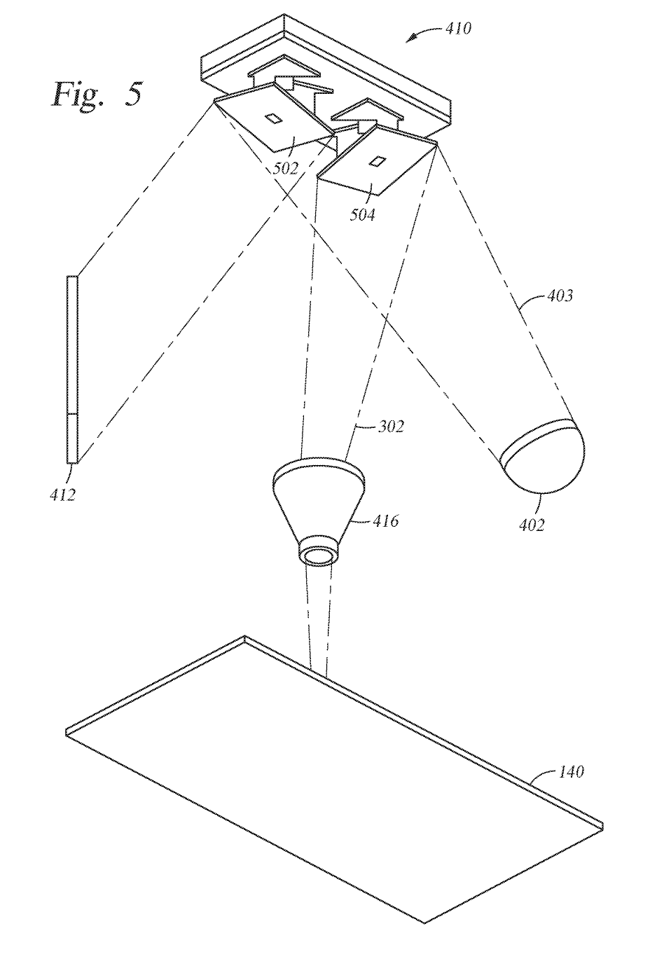

FIG. 5 schematically illustrates the beam 403 being reflected by two mirrors 502, 504 of the DMD 410. As shown, the mirror 502, which is at “off” position, reflects the beam 403 generated from the light source 402 to the light dump 412. The mirror 504, which is at “on” position, forms the write beam 302 by reflecting the beam 403 to the projection lens 416.

Each system 100 may contain any number of image projection systems 301, and the number of image projection systems 301 may vary by system. In one embodiment there are 84 image projection systems 301. Each image projection system 301 may comprise 40 diodes, or any number of diodes. A problem arises when trying to maintain a large number of diodes as higher power is required to handle such large numbers of diodes. One solution may be to order the diodes in series; however, a need exists for the detection of a non-functioning diode when organized in a series as described below.

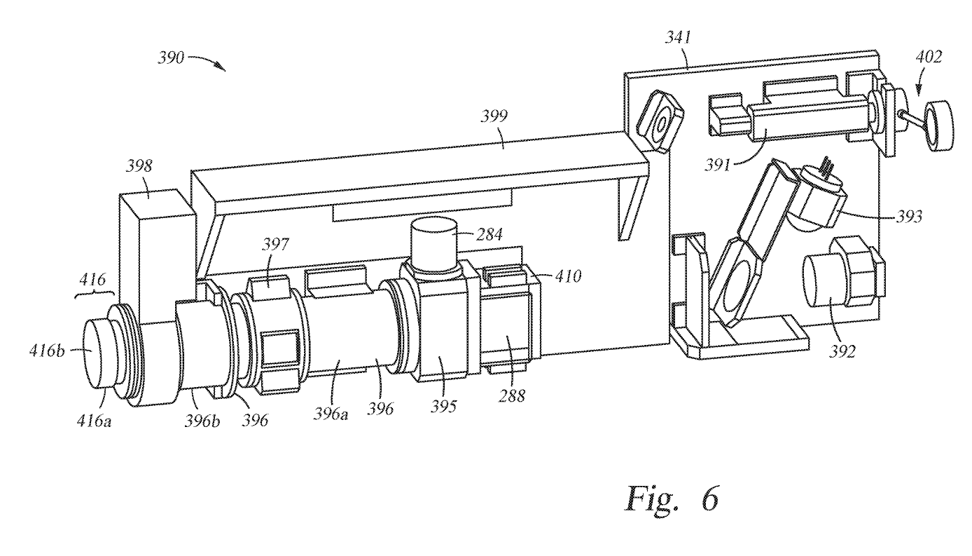

FIG. 6 is a perspective view of an image projection apparatus 390 according to one embodiment. The image projection apparatus 390 is used to focus light to a certain spot on a vertical plane of a substrate 140 and to ultimately project an image onto that substrate 140. The image projection apparatus 390 includes two subsystems. The image projection apparatus 390 includes an illumination system and a projection system. The illumination system includes at least a light pipe 391 and a white light illumination device 392. The projection system includes at least a DMD 410, a frustrated prism assembly 288, a beamsplitter 395, one or more projection optics 396a, 396b, a distortion compensator 397, a focus motor 398 and a projection lens 416 (discussed supra). The projection lens 416 includes a focus group 416a and a window 416b.

Light is introduced to the image projection apparatus 390 from the light source 402. The light source 402 may be an actinic light source. For example, the light source 402 may be a bundle of fibers, each fiber containing one laser. In one embodiment, the light source 402 may be a bundle of about 100 fibers. The bundle of fibers may be illuminated by laser diodes. The light source 402 is coupled to the light pipe (or kaleido) 391. In one embodiment, the light source 402 is coupled to the light pipe 391 through a combiner, which combines each of the fibers of the bundle.

Once light from the light source 402 enters into the light pipe 391, the light bounces around inside the light pipe 391 such that the light is homogenized and uniform when it exits the light pipe 391. The light may bounce in the light pipe 391 up to six or seven times. In other words, the light goes through six to seven total internal reflections within the light pipe 391, which results in the output of uniform light.

The image projection apparatus 390 may optionally include various reflective surfaces (not labeled). The various reflective surfaces capture some of the light traveling through the image projection apparatus 390. In one embodiment, the various reflective surfaces may capture some light and then help direct the light to a light level sensor 393 so that the laser level may be monitored.

The white light illumination device 392 projects broad-band visible light, which has been homogenized by the light pipe 391, into the projection system of image projection apparatus 390. Specifically, the white light illumination device 392 directs the light to the frustrated prism assembly. The actinic and broad-band light sources may be turned on and off independently of one another.

The frustrated prism assembly 288 functions to filter the light that will be projected onto the surface of the substrate 140. The light beam is separated into light that will be projected onto the substrate 140 and light that will not. Use of the frustrated prism assembly 288 results in minimum energy loss because the total internal reflected light goes out. The frustrated prism assembly 288 is coupled to a beamsplitter 395.

A DMD 410 is included as part of the frustrated cube assembly. The DMD 410 is the imaging device of the image projection apparatus 390. Use of the DMD 410 and frustrated prism assembly 288 help to minimize the footprint of each image projection apparatus 390 by keeping the direction of the flow of illumination roughly normal to the substrate 140 all the way from the light source 402 that generates the exposure illumination to the substrate focal plane.

The beamsplitter 395 is used to further extract light for alignment. More specifically, the beamsplitter 395 is used to split the light into two or more separate beams. The beamsplitter 395 is coupled to the one or more projection optics 396. Two projection optics 396a, 396b are shown in FIG. 6.

In one embodiment, a focus sensor and camera 414 is attached to the beamsplitter 395. The focus sensor and camera 414 may be configured to monitor various aspects of the imaging quality of the image projection apparatus 390, including, but not limited to, through lens focus and alignment, as well as mirror tilt angle variation. Additionally, the focus sensor and camera 414 may show the image, which is going to be projected onto the substrate 140. In further embodiments, the focus sensor and camera 414 may be used to capture images on the substrate 140 and make a comparison between those images. In other words, the focus sensor and camera 414 may be used to perform inspection functions.

Together the projection optics 396, the distortion compensator 397, the focus motor 398, and the projection lens 416 prepare for and ultimately project the image from the DMD 410 onto the substrate 140. Projection optics 396a is coupled to the distortion compensator 397. The distortion compensator 397 is coupled to projection optics 396b, which is coupled to the focus motor 398. The focus motor 398 is coupled to the projection lens 416. The projection lens 416 includes a focus group 416a and a window 416b. The focus group 416a is coupled to the window 416b. The window 416b may be replaceable.

The light pipe 391 and white light illumination device 392 are coupled to a first mounting plate 341. Additionally, in embodiments including additional various reflective surfaces (not labeled) and a light level sensor 393, the various reflective surfaces and the light level sensor 393 may also be coupled to the first mounting plate 341.

The frustrated prism assembly 288, beamsplitter 395, one or more projection optics 396a, 396b and distortion compensator 397 are coupled to a second mounting plate 399. The first mounting plate 341 and the second mounting plate 399 are planar, which allows for precise alignment of the aforementioned components of the image projection apparatus 390. In other words, light travels through the image projection apparatus 390 along a single optical axis. This precise alignment along a single optical axis results in an apparatus that is compact. For example, the image projection apparatus 390 may have a thickness of between about 80 mm and about 100 mm.

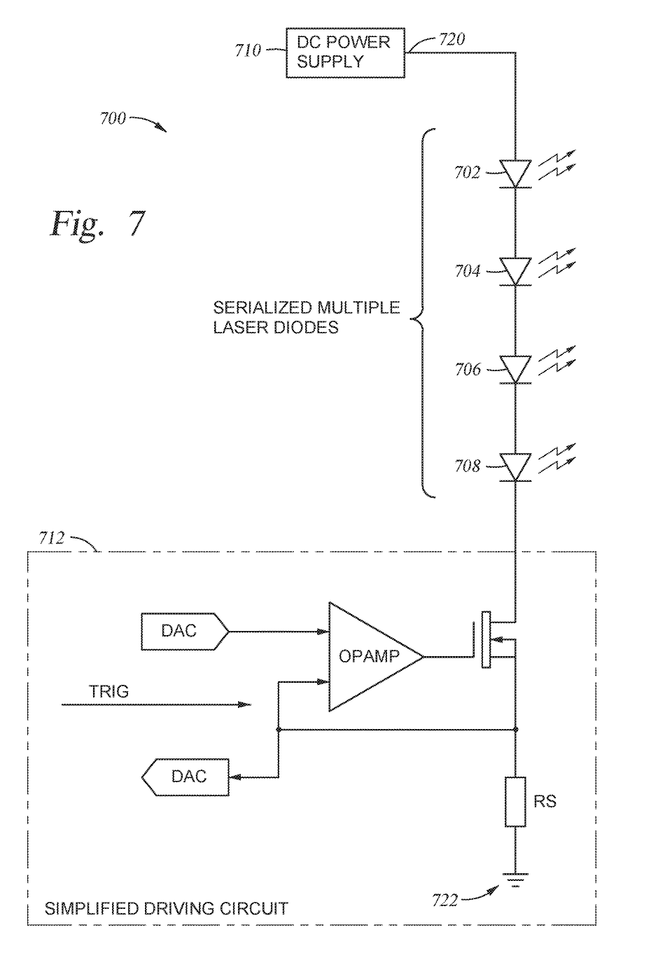

FIG. 7 illustrates a perspective schematic view of a system 700 operating four laser diodes 702, 704, 706, 708, however any number of laser diodes may be utilized, such as five laser diodes, eight laser diodes, or more depending on the electrical design and/or electronics design. The laser diodes 702, 704, 706, 708 may be organized in a serialization. The serialization may reduce the overall switching current from a power supply. The series of laser diodes 702, 704, 706, 708 may be connected with a DC power supply 710 at a first end 720, and connected with a simplified driving circuit 712 at a second end 722. The serialization of laser diodes 702, 704, 706, 708 may be between the first end 720 and the second end 722.

By placing, for example, four laser diodes in series, a reduced current is achieved. A reduction in current may be required when switching between, for example, one laser diode and four laser diodes. If a system consists of multiple diodes in series, a reduction in the overall current may be significant. However, in doing so, the ability to control each individual laser diode may be lost. There is a need to operate laser diodes with higher currents, therefore requiring the laser diodes to be operated in series. Furthermore, the embodiment of FIG. 7 may not operate efficiently when higher electrical currents are required, such as, for example, electrical currents above 0.5 amperes, such as a current of 2.0 amperes.

In the embodiment of FIG. 7, each laser diode 702, 704, 706, 708 may not be individually controlled. As such, a problem arises when any one of the laser diodes 702, 704, 706, 708 of FIG. 7 fails. With continued reference to FIG. 7, when one laser diode 702, 704, 706, 708 fails, all laser diodes 702, 704, 706, 708 of the series also fail. For example, if the failure of a laser diode occurs due to an open circuit, the entire series of laser diodes also fail. In the case of a failed laser diode a determination must be made as to which laser diode has failed. However, in the embodiment of FIG. 7 all laser diodes must function in order to determine which specific laser diode has failed.

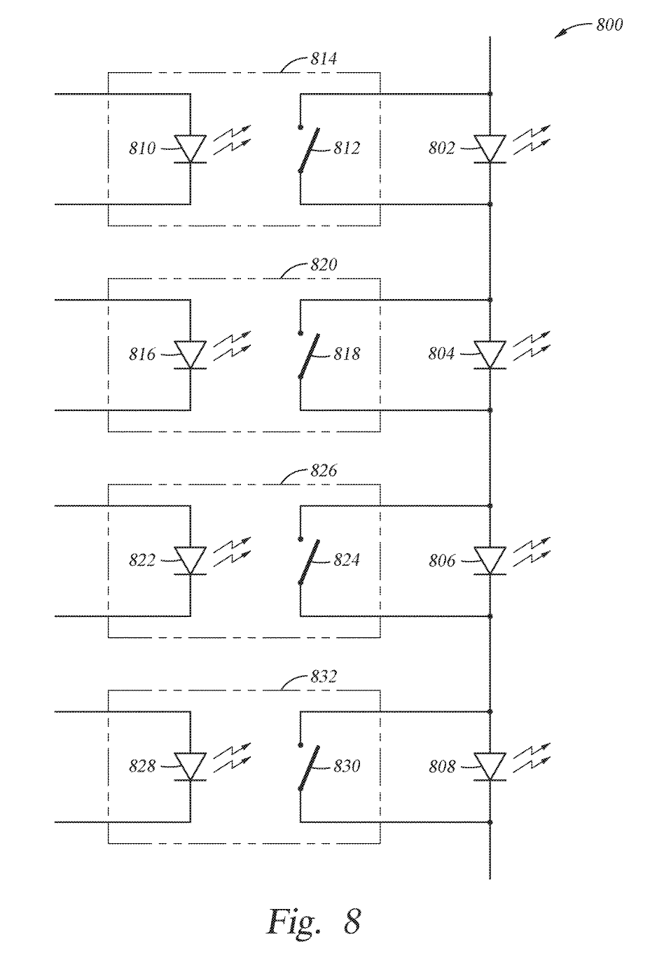

In order to correct for, or account for the problem as illustrated in FIG. 7, a switch may be utilized in connection with each laser diode. The switch may be an optical-coupled solid state relay 814, 820, 826, 832 as shown in FIG. 8. The optical-coupled solid state relay may comprise an LED and/or a switch. The switch may receive digital information to control the turning on and/or turning off of the switch, thus creating the ability to switch and control all laser diodes at the same time. Furthermore, the ability to control each laser diode digitally may be had.

In order to detect laser diode failure and functionality an optical-coupled solid state relay may be utilized in connection with each laser diode within the system. FIG. 8 illustrates a perspective schematic view of a system 800 with optical-coupled solid state relays 814, 820, 826, 832 employed on each laser diode 802, 804, 806, 808. Each optical-coupled solid state relay 814, 820, 826, 832 may allow for the control of the respective optical-coupled solid state relay 814, 820, 826, 832 by a digital control (not shown). The optical-coupled solid state relay 814, 820, 826, 832 may each contain an LED 810, 816, 822, 828 and a switch 812, 818, 824, 830. The digital control may turn on or turn off the optical-coupled solid state relays 814, 820, 826, 832 by closing or opening the switch 812, 818, 824, 830 to complete the circuit.

A detection of a failure of the system 800 may be made at any time. In some embodiments, the failure or fault detection may occur in the image projection apparatus 390, for example, within or by the light level sensor 393, discussed supra. A detection of a failure of the system 800 may be completed by a check of the laser diodes 802, 804, 806, 808. A system failure may be detected by turning on an LED 810, 816, 822, 828 of the system 800 via a switch 812, 818, 824, 830. The turning on of an individual LED 810, 816, 822, 828 within the laser diode 802, 804, 806, 808 (by closing the switch 812, 818, 824, 830) stops the laser diode 802, 804, 806, 808 from functioning. Upon the shutting down of a laser diode 802, 804, 806, 808 a measurement of optic output intensity from the laser diodes 802, 804, 806, 808 may be taken. If a change in the optic intensity occurs then the diode is functional. However, if no change in the optic intensity measurement is found, than the individual laser diode is non-functioning. A controller (not shown) may be used in the system 800 for the detection of a failure within the laser diodes 802, 804, 806, 808. Furthermore, if a reduction in optic output intensity is detected, but the reduction is not as much as expected, then it can easily be determined that the laser diode is nearing the end of the functional life. The controller may perform a digital scan of the optical-coupled solid state relays 814, 820, 826, 832 as shown in FIG. 8. A digital scan of the optical-coupled solid state relays 814, 820, 826, 832 may provide information regarding the status of the optical-coupled solid state relays 814, 820, 826, 832, such as, by way of example only, information regarding the optic output intensity of each of the laser diodes 802, 804, 806, 808. The controller may also drive control current in the detection of the laser diodes 802, 804, 806, 808.

Furthermore, if the failure of a laser diode occurs due to a short in the circuitry, than only the shorted laser diode may fail while the other laser diodes in the series may still function. In the case of a short, however, the current to the laser diodes and/or circuitry may be affected. In addition to laser diode failure or fault detection, however, shorting of the failed laser diode allows other diodes in the series to function normally.

Additionally, a laser diode may fail due to a failure in the laser cavity. In this failure mode no light may be output to an LED of the relay. However, the laser diode may be electrically normal in terms of I-V behaviors. As such, the other laser diodes in the series as well as the driving circuitry may function normally, however light output may be reduced.

The embodiments described herein relate to an apparatus and method for performing photolithography processes. More particularly, embodiments described herein generally relate to an apparatus and method for the digital control of optical-coupled solid state relays employed on a laser diode. Digital control of the optical-coupled solid state relays may allow for the turning on and/or turning off of the optical-coupled solid state relays and allow for the failure detection of each laser diode. Furthermore, the embodiments described herein allow for an increase in current provided to the laser diodes such that overall laser diode output for optimized illumination may be maintained while life time and tool reliability are also increased.

It will be appreciated to those skilled in the art that the preceding examples are exemplary and not limiting. It is intended that all permutations, enhancements, equivalents, and improvements thereto that are apparent to those skilled in the art upon a reading of the specification and a study of the drawings are included within the true spirit and scope of the present disclosure. It is therefore intended that the following appended claims include all such modifications, permutations, and equivalents as fall within the true spirit and scope of these teachings.

What is claimed is:

1. A processing apparatus, comprising:
a laser source; and
a control circuit comprising:
at least one laser diode; and
a relay coupled with each of the at least one laser diode, wherein the relay provides digital control of the at least one laser diode.

2. The processing apparatus of claim 1, wherein the at least one laser diode comprises four laser diodes.

3. The processing apparatus of claim 2, wherein the four laser diodes are arranged in series.

4. The processing apparatus of claim 1, wherein the at least one laser diode is a plurality of laser diodes arranged in series.

5. The processing apparatus of claim 1, wherein the relay is an optical-coupled solid state relay.

6. The processing apparatus of claim 1, wherein the at least one laser diode is a plurality of laser diodes which are able to be switched at the same time with the same current.

7. The processing apparatus of claim 1, wherein each of the at least one laser diodes are controlled digitally.

8. The processing apparatus of claim 1, wherein the relay comprises an LED and a switch.

9. A processing apparatus, comprising:
a control circuit, comprising:
two or more diodes connected in a series connection; and
an optically-coupled solid state relay connected with each diode, wherein each optically-coupled solid state relay provides digital control of a respective laser diode.

10. The processing apparatus of claim 9, wherein each optically-coupled solid state relay digitally controls at least one diode.

11. The processing apparatus of claim 9, further comprising four diodes connected in a series connection.

12. The processing apparatus of claim 9, wherein the two or more diodes are able to be switched at the same time with the same current.

13. The processing apparatus of claim 9, wherein the optical-coupled solid state relay comprises an LED and a switch.

14. The processing apparatus of claim 9, wherein the at least two diodes are controlled digitally.

15. A method for detecting the failure of a laser diode, comprising:
digitally scanning a relay, wherein the relay is connected with the laser diode;
driving control current to the laser diode; and
measuring the optic output intensity at the relay of each laser diode.
